(19) United States
(12) Patent Application Publication
(10) Pub. No.: US 2002/0163010 A1
(43) Pub. Date: Nov. 7, 2002

(54) Wide bandgap semiconductor structure, semiconductor device including the structure, and methods of forming the structure and device

(75) Inventors: Ravindranath Droopad, Chandler, AZ (US); Dirk C. Jordan, Gilbert, AZ (US); Zhiyi Yu, Gilbert, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Motorola, Inc.

(21) Appl. No.: 09/849,172

(22) Filed: May 4, 2001

(51) Int. Cl. H01L 31/0328

(52) U.S. Cl. 257/190; 257/184; 257/201

(57) ABSTRACT

High quality epitaxial layers (26) of wide bandgap materials can be grown overlying monocrystalline substrates (22) such as large silicon wafers by forming a compliant substrate for growing the monocrystalline layers. One way to achieve the formation of a compliant substrate includes first growing an accommodating buffer layer (24) on a silicon wafer (22). The accommodating buffer layer (24) is a layer of monocrystalline oxide or nitride spaced apart from the silicon wafer (22) by an amorphous interface layer of silicon oxide (28). The layer of wide bandgap material (26) can be used to form electronic devices such as high frequency devices or light emitting devices such as lasers and light emitting diodes.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a wide bandgap semiconductor layer formed overlying a monocrystalline substrate.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

In particular, if a wide bandgap material could be formed over a substrate such as a silicon wafer, optical and/or high frequency devices could be formed using the wide bandgap material. Furthermore, the devices including the wide bandgap material could be integrated with devices formed within the substrate.

Accordingly, a need exists for a semiconductor structure that provides a high quality, wide bandgap monocrystalline film or layer formed over a monocrystalline substrate and for a method of forming the structure.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer; and

FIG. 5 illustrates a semiconductor device structure in accordance with another embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

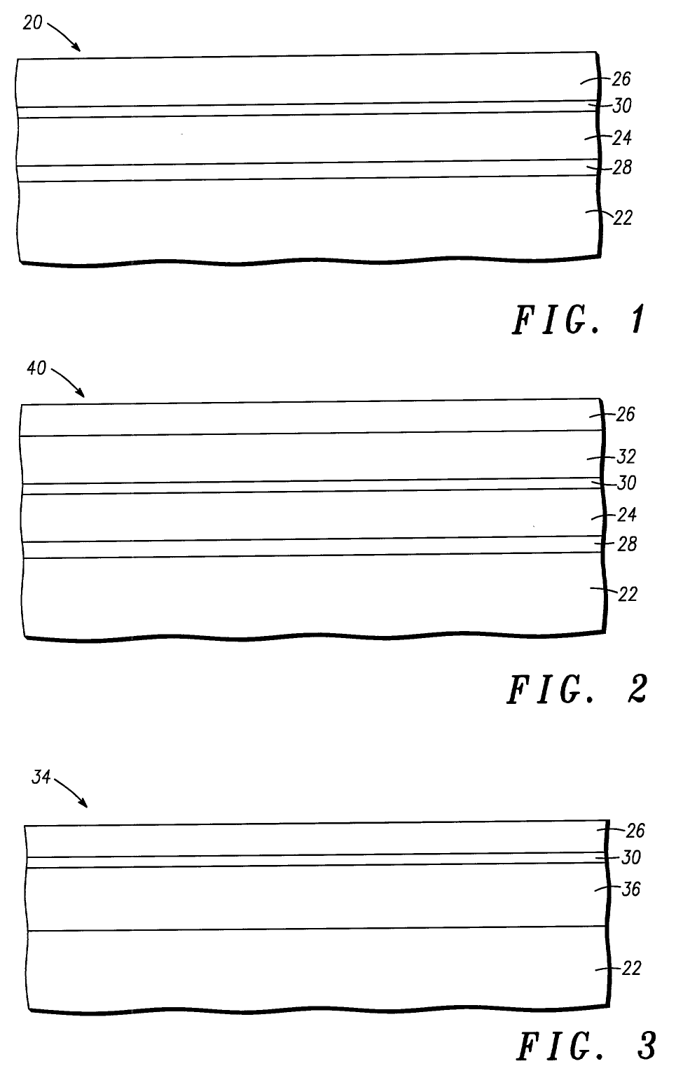

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline wide bandgap semiconductor material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and wide bandgap material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a unit cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline wide bandgap material layer 26.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied wide bandgap material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, perovskite oxides such as alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. In accordance with various embodiments of the present invention, layer 26 includes a wide bandgap material such as SiC, GaN, AIN, InN, and alloys of such compounds.

Template 30 materials are generally configured to chemically bond to the surface of the accommodating buffer layer 24 at selected sites and provide sites for the nucleation of the epitaxial growth of monocrystalline material layer 26. As discussed in greater detail below, in accordance with an exemplary embodiment of the invention, layer 30 comprises TiC.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer serves to provide a lattice compensation when the lattice constant of the accommodating buffer layer cannot be adequately matched to the overlying wide bandgap material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28.

As explained in greater detail below, amorphous layer 36 may be formed by first forming an accommodating buffer layer and an amorphous interface layer in a similar manner to that described above. Monocrystalline template layer 30 is then formed overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and monocrystalline layer 26 (subsequent to layer 30 formation) relieves stresses between layers 22 and 30 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 30 to relax.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{l-z}TiO₃ where z ranges from 0 to 1 and the amorphous intermediate layer is a layer of silicon oxide (SiOᵥ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the wide bandgap semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

Monocrystalline wide bandgap material layer 26 is a layer of SiC, GaN, AIN, InN or an alloy of one of these materials, having a thickness of about 1 nm to about 100 micrometers (μm) and preferably a thickness of about 0.5 μm to 10 μm. The thickness generally depends on the application for which the layer is being prepared. In accordance with this embodiment of the invention, template layer 30 is preferably a layer of TiC, having a thickness of about 0.1-10 nm.

### EXAMPLE 2

This example provides exemplary materials useful in structure 34, as illustrated in FIG. 3. Substrate material 22, template layer 30, and monocrystalline wide bandgap material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{l-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

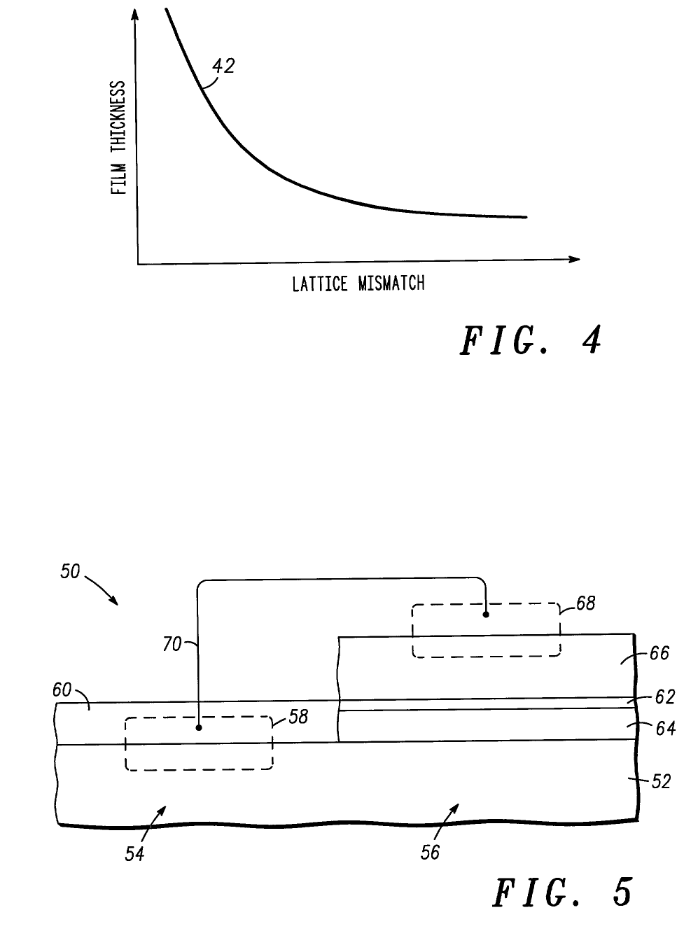

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is SiC and the accommodating buffer layer is monocrystalline SrₓBaₗ₋ₓTiO₃, substantial matching of crystal lattice constants of the two materials is achieved, wherein the crystal orientation of the grown layer is rotated by 45° with respect to the orientation of the host monocrystalline oxide. In some instances, a crystalline semiconductor buffer layer between the host oxide and the grown monocrystalline wide bandgap material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of greater or equal to 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 750° C. or more. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered monocrystal with the crystalline orientation rotated by 45° with respect to the ordered 2×1 crystalline structure of the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, a template layer, which is conducive to the subsequent growth of an epitaxial layer of a desired monocrystalline wide bandgap material, is formed. In accordance with one embodiment of the invention, a TiC template layer 30 is formed by terminating the growth of titantate layer 24 with about one or more monolayers (e.g., about 0.1 nm to about 5 nm) of titanium and exposing the titanium layer to a carbon-containing precursor that reacts with the titanium layer to form TiC. For example, the TiC layer can be formed by exposing the titanium layer to acetylene or methane in a reaction chamber with a process temperature of about 800° C. to about 1000° C. Such a process may be carried out in the same deposition chamber used to form titanate layer 24, a different chamber in the same system used to form layer 24, or in an entirely separate system.

In accordance with an alternate embodiment of the invention, titanate layer 24 may be graded by varying the titanium composition across the thickness of the film. In particular, the titanium composition may range from a low value at a lower portion of the film to a high value (e.g., 1) at the top of the film, such that the top 5-10 Å of the layer is titanium. The titanium is then exposed to a carbon containing precursor to form TiC template layer 30.

In accordance with yet another embodiment of the invention, template layer 30 may be formed by depositing a TiC layer onto titanate layer 24. For example, layer 30 may be formed by sputtering TiC onto titanate layer 24, either in the same reactor or using a separate reactor.

The structure illustrated in FIG. 2 can be formed by the process discussed above with the addition of an additional buffer layer deposition step. The buffer layer is formed overlying the template layer before the deposition of the monocrystalline material layer. If the buffer layer is a monocrystalline material comprising a compound semiconductor superlattice, such a superlattice can be deposited, by MBE for example, on the template described above.

Structure 34, illustrated in FIG. 3, may be formed by growing an accommodating buffer layer, forming an amorphous oxide layer over substrate 22, and growing template layer 30 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 30. Alternatively, the anneal process may be carried out subsequent to growth of all or part of layer 26.

In accordance with one aspect of this embodiment, layer 36 is formed by exposing substrate 22, the accommodating buffer layer, the amorphous oxide layer, and template layer 30 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 30 during the anneal process.

The process described above illustrates a process for forming a semiconductor structure including a silicon substrate, an overlying oxide layer, and a monocrystalline wide bandgap material layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown.

FIG. 5 illustrates schematically, in cross section, a device structure 50 in accordance with a further embodiment of the invention. Device structure 50 includes a monocrystalline semiconductor substrate 52, preferably a monocrystalline silicon wafer. Monocrystalline semiconductor substrate 52 includes two regions, 54 and 56. An electrical semiconductor component generally indicated by the dashed line 58 is formed, at least partially, in region 54. Electrical component 58 can be a resistor, a capacitor, an active semiconductor component such as a diode ora transistor or an integrated circuit such as a CMOS integrated circuit. The electrical semiconductor component in region 54 can be formed by conventional semiconductor processing as is well known and widely practiced in the semiconductor industry. A layer of insulating material 60 such as a layer of silicon oxide or the like may overlie electrical semiconductor component 58.

Insulating material 60 and any other layers that may have been formed or deposited during the processing of semiconductor component 58 in region 54 are removed from the surface of region 56 to provide a bare silicon surface in that region. As is well known, bare silicon surfaces are highly reactive and a native silicon oxide layer can quickly form on the bare surface. A layer of strontium or strontium and oxygen is deposited onto the native oxide layer on the surface of region 56 and is reacted with the oxidized surface to form a first template layer (not shown). In accordance with one embodiment of the invention a monocrystalline oxide layer is formed overlying the template layer by a process of molecular beam epitaxy. Reactants including strontium, titanium and oxygen are deposited onto the template layer to form the monocrystalline oxide layer. During the deposition, the partial pressure of oxygen is initially set near the minimum necessary to fully react with the strontium and titanium to form the monocrystalline strontium titanate layer. As the monocrystalline oxide forms, the partial pressure of oxygen is increased to form an amorphous layer between the growing crystalline layer and the substrate.

In accordance with an embodiment of the invention, the step of depositing the monocrystalline oxide layer is terminated by forming a layer (e.g., 0.1 to about 1 nm) of titanium and then exposing the titanium to a carbon source to form a template layer 62 of TiC.

In accordance with one aspect of the present embodiment, after layer 62 formation, the monocrystalline titanate layer is exposed to an anneal process such that the titanate layer forms an amorphous oxide layer 64. A wide bandgap material layer 66 is then epitaxially grown over layer 62, using the techniques described above.

In accordance with a further embodiment of the invention, a semiconductor component, generally indicated by a dashed line 68 is formed, at least partially, in layer 66. Semiconductor component 68 can be formed by processing steps conventionally used in the fabrication of semiconductor material devices. Semiconductor component 68 can be any active or passive component or another component that utilizes and takes advantage of the physical properties of the wide bandgap material layer. For example, device 68 may include lasers, light emitting diode, and the like, or high frequency devices such as radio frequency devices and the like. A metallic conductor schematically indicated by the line 70 can be formed to electrically couple device 58 and device 68, thus implementing an integrated device that includes at least one component formed in the silicon substrate and one device formed in the monocrystalline wide bandgap layer.

Although illustrative structure 50 has been described as a structure formed on a silicon substrate 52 and having a strontium (or barium) titanate layer, similar devices can be fabricated using other monocrystalline substrates, oxide layers and other monocrystalline material layers as described elsewhere in this disclosure.

Clearly, those embodiments specifically describing structures having wide bandgap semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and dielectric layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising wide bandgap semiconductor materials as well as other material layers that are used to form those devices with other components that work better or are easily and/or inexpensively formed within the substrate material. This allows a device to be shrunk, the manufacturing costs to decrease, and yield and reliability to increase.

In accordance with one embodiment of this invention, a monocrystalline semiconductor or compound semiconductor wafer can be used in forming monocrystalline wide bandgap material layers over the wafer. In this manner, the wafer is essentially a “handle” wafer used during the fabrication of semiconductor electrical components within a monocrystalline wide bandgap material layer overlying the wafer. Therefore, electrical components can be formed within semiconductor materials over a wafer of at least approximately 75 millimeters in diameter and possibly at least approximately 300 millimeters.

By the use of this type of substrate, a relatively inexpensive “handle” wafer overcomes the fragile nature typical wide bandgap material wafers by placing the material over a relatively more durable and easy to fabricate base material. Therefore, an integrated circuit can be formed such that all electrical components, and particularly all active electronic devices, can be formed within or using the monocrystalline wide bandgap material layer even though the substrate itself may include a monocrystalline semiconductor material. Fabrication costs for wide bandgap devices should decrease because larger substrates can be processed more economically and more readily compared to the relatively smaller and more fragile wide bandgap material substrates.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline substrate;
a perovskite oxide accommodating buffer layer formed on the substrate;
a template formed on the buffer layer; and
a monocrystalline wide bandgap material layer formed overlying the template.

2. The semiconductor structure of claim 1, wherein the template layer comprises TiC.

3. The semiconductor structure of claim 1, wherein the monocrystalline wide bandgap material comprises a material selected from the group consisting of SiC, GaN, AIN, and InN.

4. The semiconductor structure of claim 1, wherein the monocrystalline wide bandgap material comprises an alloy including a material selected from the group consisting of SiC, GaN, AIN, and InN.

5. The semiconductor structure of claim 1, wherein the template layer is about 0.1-5 nm thick.

6. The semiconductor structure of claim 1, further comprising an amorphous layer interposed between the monocrystalline substrate and the accommodating buffer layer.

7. The semiconductor structure of claim 6, wherein the amorphous layer comprises silicon oxide.

8. The semiconductor structure of claim 1, wherein the perovskite oxide accommodating buffer layer comprises an oxide selected from the group consisting of alkaline earth metal titanates, alkaline earth metal zirconates, alkaline earth metal hafniates, alkaline earth metal tantalates, alkaline earth metal ruthenates, and alkaline earth metal niobates.

9. The semiconductor structure of claim 1, wherein the accommodating buffer layer comprises SrₓBaₗ₋ₓTiO₃, where x ranges from 0 to 1.

10. The semiconductor structure of claim 1, wherein the perovskite oxide accommodating buffer layer is monocrystalline.

11. The semiconductor structure of claim 1, wherein the perovskite oxide accommodating buffer layer is amorphous.

12. The semiconductor structure of claim 1, wherein the monocrystalline substrate comprises silicon.

13. The semiconductor structure of claim 1, further comprising an active device formed at least partially in the monocrystalline wide bandgap material layer.

14. The semiconductor structure of claim 13, wherein the active device include a light emitting diode.

15. The semiconductor structure of claim 13, wherein the active device includes a laser.

16. The semiconductor structure of claim 13, wherein the active device includes an rf device.

17. The semiconductor structure of claim 1, further comprising an electronic component formed at least partially within the monocrystalline substrate, wherein the electronic component is coupled to the active device.

18. A semiconductor structure comprising:
a monocrystalline silicon substrate;
a perovskite oxide accommodating buffer layer formed over the monocrystalline substrate;
a TiC template formed on the accommodating buffer layer; and
a monocrystalline wide bandgap material layer formed overlying the template.

19. The semiconductor structure of claim 18, wherein the wide bandgap material comprises SiC.

20. The semiconductor structure of claim 18, wherein the wide bandgap material comprises GaN.

21. The semiconductor structure of claim 18, wherein the wide bandgap material comprises AIN.

22. The semiconductor structure of claim 18, wherein the wide bandgap material comprises InN.

23. The semiconductor structure of claim 18, wherein the perovskite oxide accommodating buffer layer is amorphous.

24. The semiconductor structure of claim 18, wherein the perovskite oxide accommodating buffer layer is monocrystalline.

25. The semiconductor structure of claim 18, further comprising an amorphous layer interposed between the monocrystalline silicon substrate and the accommodating buffer layer.

26. The semiconductor structure of claim 25, wherein the amorphous layer comprises silicon oxide.

27. The semiconductor structure of claim 18, further comprising an optical device formed using the monocrystalline wide bandgap material.

28. The semiconductor of claim 18, further comprising a high frequency device formed using the monocrystalline wide bandgap material.

29. The semiconductor structure of claim 18, further comprising an electrical component formed within the silicon substrate.

30. The semiconductor structure of claim 18, wherein the accommodating buffer layer comprises an oxide formed as a monocrystalline oxide that is subsequently heat treated to convert monocrystalline oxide to an amorphous oxide.

31. The semiconductor structure of claim 18, wherein the accommodating buffer layer comprises an oxide selected from the group consisting of alkaline earth metal titanates, alkaline earth metal zirconates, alkaline earth metal hafniates, alkaline earth metal tantalates, alkaline earth metal ruthenates, and alkaline earth metal niobates.

32. A process for fabricating a semiconductor structure, comprising the steps of:
providing a monocrystalline silicon substrate;
depositing a monocrystalline perovskite oxide film overlying the monocrystalline silicon substrate;
forming a template layer overlying the accommodating buffer layer; and
epitaxially growing a wide bandgap semiconductor material adjacent the template layer.

33. The process of claim 32, further comprising the step of annealing the monocrystalline perovskite oxide film to cause the accommodating buffer layer to change from a monocrystalline structure to an amorphous structure.

34. The process of claim 33, wherein the step of annealing comprises the step of rapid thermal annealing.

35. The process of claim 32, further comprising the step of forming a first template layer on the monocrystalline silicon substrate.

36. The process of claim 32, wherein the step of providing a monocrystalline silicon substrate includes providing a (100) silicon substrate.

37. The process of claim 32, wherein the step of epitaxially growing a wide bandgap material includes growing a layer comprising material selected from the group consisting of SiC, GaN, AIN, and InN.

38. The process of claim 32, wherein the step of forming a template comprises the steps of:
forming a layer of titanium; and
exposing the layer of titanium to a carbon-containing precursor to form TiC.

39. The process of claim 38, wherein the exposing step includes heating the substrate to a temperature of about 800° C. to about 1000° C.

40. The process of claim 32, wherein the step of forming a template comprises the steps of:
terminating the growth of the accommodating buffer layer with about 0.5 nm to about 1 nm of titanium; and
exposing the titanium to a carbon-containing precursor to form TiC.

41. The process of claim 40, wherein the exposing step includes heating the substrate to a temperature of about 800° C. to about 1000° C.

42. The process of claim 32, wherein the step of forming a template comprises the step of depositing a layer of TiC onto the accommodating buffer layer.

43. The process of claim 32, further comprising forming an electronic component at least partially within the wide bandgap semiconductor material.

44. The process of claim 43, wherein the step of forming an electronic component includes forming a light emitting diode.

44. The process of claim 43, wherein the step of forming an electronic component includes forming a laser.

45. The process of claim 43, wherein the step of forming an electronic component includes forming a high frequency device.

44. The process of claim 32, further comprising forming an electronic component at least partially within the monocrystalline substrate.

45. A high frequency microelectronic device comprising:
a monocrystalline silicon substrate;
an perovskite oxide accommodating buffer layer formed over the monocrystalline substrate;
a TiC template formed on the accommodating buffer layer;
a monocrystalline wide bandgap material layer formed overlying the template; and
a high frequency electronic component formed at least partially within the monocrystalline wide bandgap material.

46. The high frequency microelectronic device of claim 45, wherein the monocrystalline wide bandgap material layer comprises a material selected from the group consisting of SiC, GaN, AIN, and InN.

47. The high frequency microelectronic device of claim 45, further comprising an electronic component formed at least partially within the monocrystalline silicon substrate.

48. An optical microelectronic device comprising:
a monocrystalline silicon substrate;
a perovskite oxide accommodating buffer layer formed over the monocrystalline substrate;
a TiC template formed on the accommodating buffer layer;
a monocrystalline wide bandgap material layer formed overlying the template; and
an optical component formed at least partially within the monocrystalline wide bandgap material.

49. The optical microelectronic device of claim 48, wherein the monocrystalline wide bandgap material layer comprises a material selected from the group consisting of SiC, GaN, AIN, and InN.

50. The optical microelectronic device of claim 48, wherein the optical component comprises a laser.

51. The optical microelectronic device of claim 48, wherein the optical component comprises a light emitting diode.

52. The optical microelectronic device of claim 48, further comprising an electronic component formed at least partially within the monocrystalline silicon substrate.
